(19) United States
(12) Patent Application Publication
(10) Pub. No.: US 2009/0121762 A1
(43) Pub. Date: May 14, 2009

(54) TIMEBASE VARIATION COMPENSATION IN A MEASUREMENT INSTRUMENT

(75) Inventor: Kalev SEPP, Portland, OR (US)

Correspondence Address: THOMAS F. LENIHAN;TEKTRONIX, INC., 14150 S. W. KARL BRAUN DRIVE, P.O. BOX 500 (50-LAW), BEAVERTON, OR, 97077-0001, US

(73) Assignee: TEKTRONIX, INC., Beaverton, OR (US)

(21) Appl. No.: 11/937,749

(22) Filed: Nov. 9, 2007

(51) Int. Cl. H03L 7/00

(52) U.S. Cl. 327/162

(57) ABSTRACT

Timebase variation compensation in a measurement instrument is achieved by simultaneously acquiring both a signal under test and a reference signal. The reference signal is derived from a source that has very stable timing with respect to the timebase. Timing variations are measured from the acquired signals. Timing variations detected in the reference signal are deemed to reflect variations in the timebase of the test and measurement instrument. The timing variations in the reference signal are used to detect, and compensate for, timebase variation in the signal under test to produce a corrected signal under test that reflects the actual timing variations present in the signal under test.

### FIELD OF THE INVENTION

The present invention relates to timing accuracy in a measurement instrument, and more particularly to a timebase variation compensation that allows very accurate jitter and timing error measurements.

### BACKGROUND OF THE INVENTION

The timebase of a test and measurement instrument refers to a sample clock signal which determines the times at which an input signal under test (SUT) is sampled. Prior art FIG. 1 shows one cycle of an input signal under test 105 and a sample clock 110. Ideally, the interval T1, T2 between each sample of the input signal is constant, as shown in prior art FIG. 1.

Referring to FIG. 2, a first waveform 105 and a second waveform 210 are overlaid to indicate that the signal under test is exhibiting “jitter” (i.e., timing variations at the signal source). That is, waveform 210 should exactly overlay waveform 105, but has shifted in phase such that it is delayed with respect to waveform 105. Measuring jitter is a commonly performed task of a modern oscilloscope, which allows identification and quantification of the problem, so that the designer can correct the problem in his circuit under test. Note that from the “point of view” of oscilloscope, the only indication that the signal under test 105, 210 is exhibiting jitter is the changing amplitude values of the acquired signal samples. For example, the sample taken from waveform 210 at the beginning of period T1 of FIG. 2 is occurring earlier on the waveform due to the delay of the waveform with respect to the sample clock 110, which causes that particular sample to exhibit a lower amplitude value than the comparable sample taken from waveform 110.

In the examples of FIGS. 1 and 2, it was assumed that the sample clock of the oscilloscope was “perfectly” stable. Unfortunately, such is not always the case. That is, although manufacturers of modern test and measurement instruments would prefer to use the best available timebase source, they are constrained by design tradeoffs including cost, space, power, complexity, among others. Therefore, the timebases used in modern test and measurement instruments tend to be somewhat less stable than those used in a dedicated, highly stable signal source, such as a high quality Bit Error Rate Tester (BERT) clock, radio frequency (RF) generator, high quality arbitrary waveform generator (AWG) or the like. As signals to be tested get faster, the accuracy of the timebase for the measurement instrument, such as a digital storage oscilloscope (DSO), becomes more critical for precise jitter and other timing related measurements.

Timebase variations in a test and measurement instrument, such as an oscilloscope, occur due to instrument circuit noise, delay intervals to generate a high sample rate sample clock from a lower rate clock, etc. The result is that the intervals between sample pulses of the sample clock vary from the ideal. The timebase variation subsequently affects the jitter and timing error measurements of signals from a device under test, introducing an unknown error into the measurements. Although the timebase may be calibrated in the factory, there still exist errors since the factory environment and the measurement environment are not the same. Differences in temperature, aging of components, etc. all have an impact upon timebase variations.

Such a timebase error in an oscilloscope is shown in FIG. 3. Note that the input signal under test 105 is stable, but sample clock 110 has undergone a phase error and has been delayed slightly, as shown in subsequent sample clock waveform 310. The oscilloscope “believes” that its sample clock is perfectly stable, because the oscilloscope has no way of detecting that the sample clock has been disturbed, and that subsequent sample clock 310 is exhibiting a delay with respect to sample clock 110.

All that the oscilloscope can “know” is that the samples taken with sample clock 110 differ in amplitude from those taken with subsequent sample clock 310. Thus, the oscilloscope interprets the data acquisitions as coming from a jittery signal under test, just as it did with the data of FIG. 2. It is important to note that in this case, there is nothing wrong with waveform 110 of FIG. 3, but the oscilloscope will incorrectly label the test results as indicating jitter error in the signal under test, and will fail a perfectly acceptable signal. In this regard, very high frequency signals may have relatively tight jitter tolerances, such as those for 2.5 Gb/s PCI-Express 8b10b serial data, 10 Gb/s Ethernet 64b/66b serial data or 12.5 Gb/s non-standard PRBS data streams. In such cases especially, timebase variations occurring in the measurement instrument may result in measurement values which erroneously indicate that the signal under test is outside of tolerance.

What is desired is an apparatus and method that overcomes these difficulties and produces a corrected signal under test that reflects the actual timing variations present in the signal under test.

### SUMMARY OF THE INVENTION

Accordingly, the present invention provides timebase variation compensation in a test and measurement instrument by simultaneously acquiring both a signal under test and a reference signal. The reference signal is derived from a source that has very stable timing with respect to the timebase. Timing variations are measured from the acquired signals. Timing variations detected in the reference signal are deemed to reflect variations in the timebase of the test and measurement instrument. The timing variations in the reference signal are used to detect, and compensate for, timebase variation in the signal under test to produce a corrected signal under test that reflects the actual timing variations present in the signal under test.

The objects, advantages and other novel features of the present invention are apparent from the following detailed description when read in conjunction with the appended claims and attached drawing.

### BRIEF DESCRIPTION OF THE DRAWING

FIG. 1 is an illustration of a signal under test and a sampling clock, as known from the prior art.

FIG. 2 is an illustration of a signal under test that is exhibiting jitter and a sampling clock, as known from the prior art.

FIG. 3 is an illustration of a signal under test and a sampling clock that is exhibiting jitter, as known from the prior art.

FIG. 4 is an illustration of a signal under test, a sampling clock that is exhibiting jitter, and a reference signal, in accordance with the subject invention.

FIG. 5 is a high level block diagram of a digital storage oscilloscope suitable for use with the subject invention

FIG. 6 is a block diagram view of a system setup for timebase variation compensation in a signal under test by a measurement instrument according to the present invention.

FIG. 7 is a graphic view of period timing trends illustrating timebase variation compensation according to the present invention.

FIG. 8 is a flow diagram view of the process of timebase variation compensation according to the present invention.

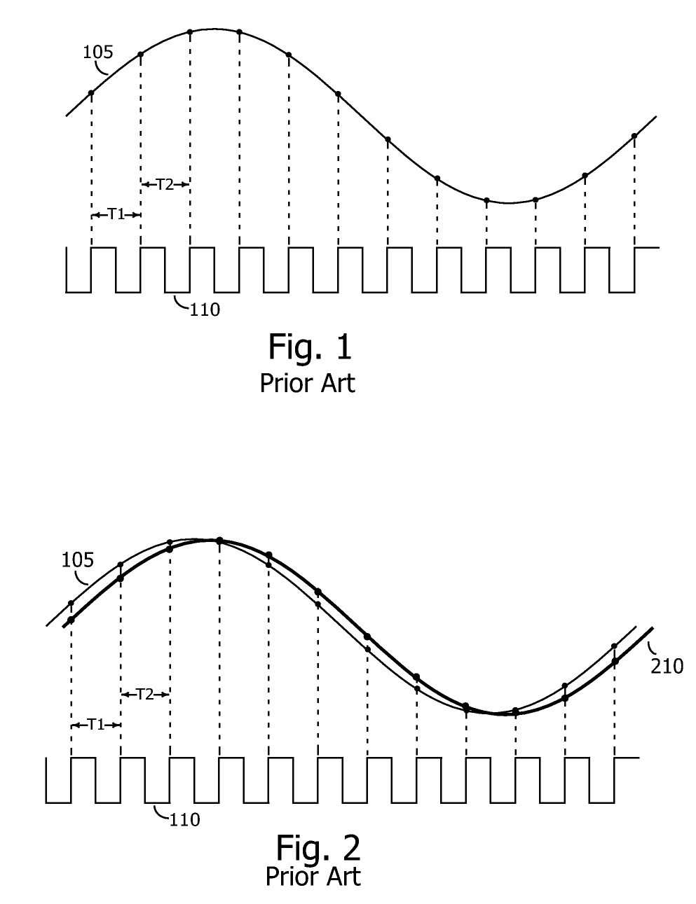

### DETAILED DESCRIPTION OF THE DRAWING

One might think that a solution to the problem would be to eliminate the effects of measurement instrument timebase variations by using the clock of the test and the measurement instrument to provide the timing for the device under test (DUT). That is, by replacing the internal clock of the device under test with the clock from the test and measurement instrument. The assumption underlying this attempted solution is that variations in the instrument timebase are reflected in the instrument clock so that such variations are canceled out when the signal from the device under test is measured. However, this method does not account for jitter and timing errors resulting from the internal clock of the device under test. Further, the normal operation of the device under test may be adversely affected when running under the clock from the test and measurement instrument, so additional compensation circuits may be needed.

One might also think that an external highly stable clock could be substituted for the clock of the test and measurement instrument. In fact, many Tektronix oscilloscopes include a terminal to which an external 10 MHz signal external clock signal will be multiplied to a higher sampling rate, thereby adversely affecting its stability. It is also not a good solution because the oscilloscope has been factory calibrated, and substitution of an external clock may require recalibration for optimum accuracy.

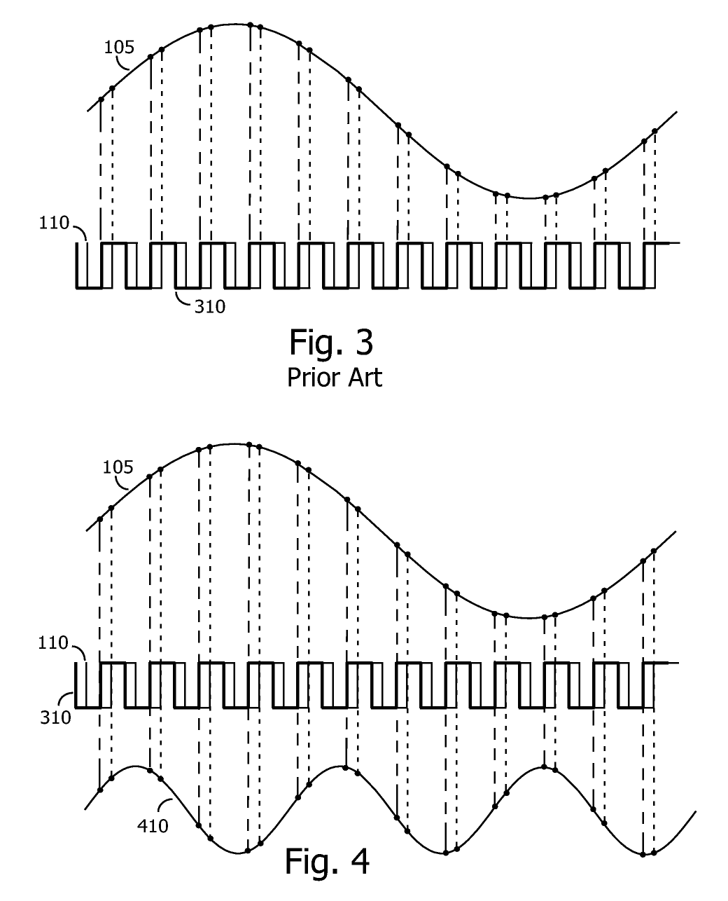

The subject invention will now be described with respect to FIGS. 4-8. FIG. 4 shows waveforms which may be helpful for understanding the subject invention. Waveforms 105, 110, and 310 operate as described above with respect to FIG. 3. FIG. 4 also shows a highly stable reference waveform 410 which is sampled at the same times as is waveform 110. Highly stable reference waveform 410 is supplied by a high precision waveform generator, as will be described below.

Referring to FIG. 4, note that the input signal under test 105 is stable, but sample clock 110 has undergone a phase error and has been delayed slightly, as shown in subsequent sample clock waveform 310. Once again, the oscilloscope “believes” that its sample clock is perfectly stable, because the oscilloscope has no way of detecting that the sample clock has been disturbed, and that subsequent sample clock 310 is exhibiting a delay with respect to sample clock 110.

As mentioned above, all that the oscilloscope can “know” is that the samples taken with sample clock 110 differ in amplitude from those taken with subsequent sample clock 310. Thus, the oscilloscope interprets the data acquisitions as coming from a jittery signal under test, just as it did with the data of FIGS. 2 and 3. It is important to note that in this case waveform 105, may, or may not, exhibit jitter of its own. For simplicity of explanation, in the example shown in FIG. 4, there is nothing wrong with waveform 105. If waveform 105 were exhibiting jitter of its own, the resulting sample values taken with sample clock 110 and subsequent sample clock 310 would be the result of both jitter in the signal under test and jitter in the sample clocks.

Note that sample clock 110 and sample clock 310 are also used to take samples of reference signal 410, simultaneously with the samples taken from signal under test 105. Remember that reference signal 410 is a highly stable precision waveform that, for practical purposes of the subject invention, is assumed to exhibit no jitter. But “jitter” on highly stable waveform 410 is being measured! Therefore, oscilloscope 500 can correctly infer that its own sample clock must be jittering, and that the amount of jitter present on samples of waveform 410 is erroneous, and must be deducted from the amount of jitter present on samples of waveform 105.

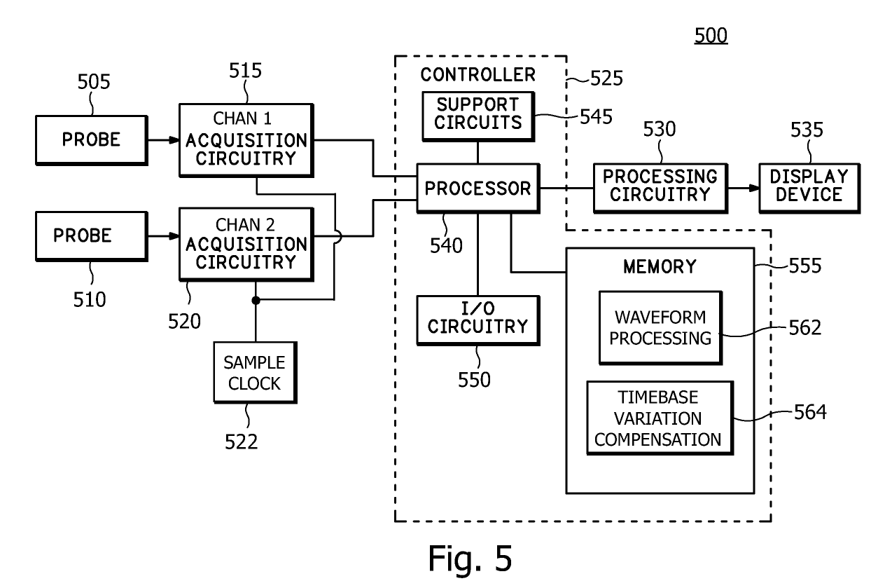

FIG. 5 depicts a high level block diagram of an oscilloscope 500 in accordance with the subject invention. In particular, oscilloscope 500 utilizes a first probe 505 and a second probe 510, and comprises Channel 1 Acquisition circuitry 515, Channel 2 Acquisition circuitry 520, a Controller 525, processing circuitry 530, and a display device 535. Probe 505 and probe 510 may be any conventional voltage or current probes suitable for respectively detecting analog voltage or current signals from a circuit under test (not shown).

For example, probes 505 and 510 may be any suitable probes which may be used to acquire real time signal information. Such probes are manufactured by Tektronix, Inc., Beaverton, Oreg. The output signals of probes 505 and 510 are respectively sent to the Channel 1 Acquisition circuitry 515 and Channel 2 Acquisition circuitry 520.

The Channel 1 Acquisition circuitry 515 and Channel 2 Acquisition circuitry 520 each include, illustratively, analog-to-digital conversion circuitry, triggering circuitry, decimator circuitry, supporting Acquisition memory, and the like. Acquisition circuitry 515 and 520 operate to digitize, at a sample rate, “S”, one or more of the signals under test to produce one or more respective acquired sample streams suitable for use by Controller 525 or processing circuitry 530. Acquisition circuitry 515 and 520, in response to commands received from Controller 525, change trigger conditions, decimator functions, and other Acquisition related parameters. Acquisition circuitry 515, 520 communicates its respective resulting sample stream to Controller 525.

Controller 525 operates to process the one or more acquired sample streams provided by the Acquisition circuitry 515 and 520 to generate respective waveform data associated with one or more sample streams. That is, given desired time per division and volts per division display parameters, Controller 525 operates to modify or rasterize the raw data associated with an acquired sample stream to produce corresponding waveform data having the desired time per division and volts per division parameters. Controller 525 may also normalize waveform data having non-desired time per division, volts per division, and current per division parameters to produce waveform data having the desired parameters. Controller 525 provides the waveform data to processing circuitry 530 for subsequent presentation on display device 535.

Processing circuitry 530 comprises data processing circuitry suitable for converting acquired sample streams or waveform data into image or video signals, which are adapted to provide visual imagery (e.g., video frame memory, display formatting and driver circuitry, and the like). Processing circuitry 530 may include display device 535 (e.g., a built-in display device) or provide output signals (e.g., via a video driver circuit) suitable for use by an external display device 535.

Controller 525 of FIG. 5 preferably comprises a Processor 540, support circuits 545, I/O circuitry 550 and Memory 555. Processor 540 cooperates with conventional support circuitry 545, such as power supplies, clock circuits, cache memory, and the like, as well as circuits that assist in executing software routines stored in Memory 555. As such, it is contemplated that some of the process steps discussed herein as software processes may be implemented within hardware, for example, as circuitry that cooperates with Processor 540 to perform various steps. Controller 525 also contains input/output (I/O) circuitry 550 that forms an interface between the various function elements communicating with Controller 525. For example, I/O circuitry 550 may comprise a keypad, pointing device, touch screen, or other means adapted to provide user input and output to Controller 525. Controller 525, in response to such user input, illustratively adapts the operations of Acquisition circuitry 515 and 550 to perform various data Acquisitions, triggering, processing, display communications, among other functions. In addition, the user input may be used to trigger automatic calibration functions or adapt other operating parameters of display device 535, logical analysis, or other data acquisition devices.

Memory 555 may include volatile memory, such as SRAM, DRAM, among other volatile memories. Memory 550 may also include non-volatile Memory devices, such as a disk drive or a tape medium, among others, or programmable memory, such as an EPROM, among others. Preferably, Memory 555 stores the timebase variation compensation program of the subject invention.

Although Controller 525 of FIG. 5 is depicted as a general purpose computer that is programmed to perform various control functions in accordance with the present invention, the invention may be implemented in hardware such as, for example, an application specific integrated circuit (ASIC). As such, it is intended that Processor 525, as described herein, be broadly interpreted as being equivalently performed by hardware, software, or by a combination thereof.

It will be appreciated by those skilled in the art that standard signal processing components (not shown), such as signal buffering circuitry, signal conditioning circuitry, and the like are also employed as required to enable the various functions described herein. For example, Acquisition circuitry 515 and 520 sample the signals under test at a sufficiently high rate to enable appropriate processing by Controller 525 or Processing circuitry 530. In this regard, Acquisition circuitry 515 and 520 sample their respective input signals in accordance with a sample clock provided by an internal Sample Clock Generator 522.

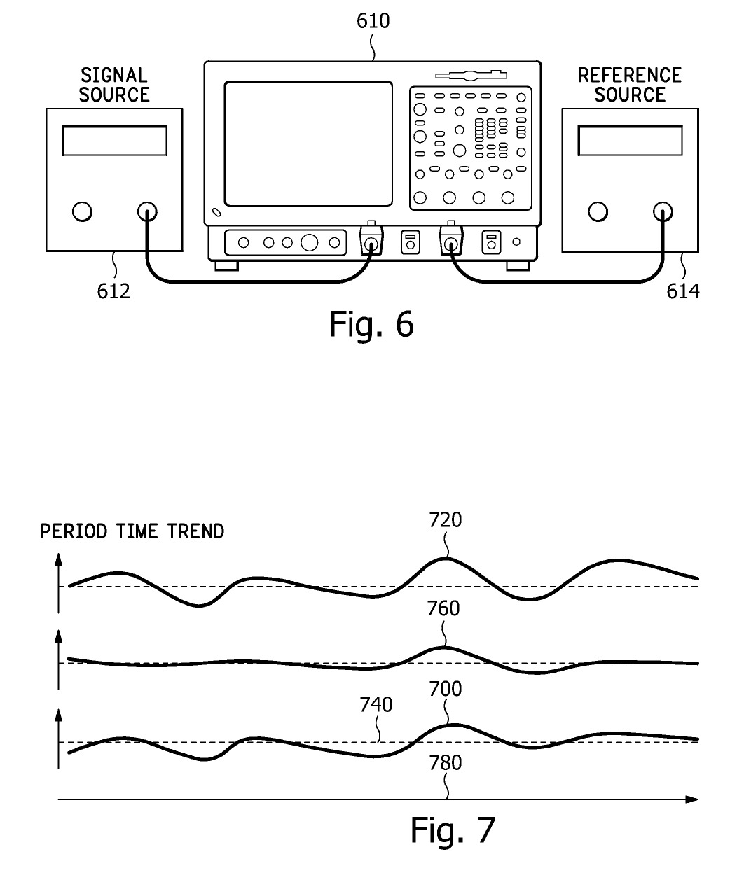

Referring now to FIG. 6, oscilloscope 500 may have a varying timebase which should be compensated for greater accuracy. A signal to be measured from a device under test 612 is coupled to one channel of the instrument 500, while a reference clock from a very high accuracy source 614, such as a high end BERT, RF generator, or arbitrary waveform generator (AWG) which is significantly more stable than the timebase of oscilloscope 500, is coupled to a second channel of the oscilloscope 500.

Three time trends are shown in FIG. 7. Referring to FIG. 7, the timebase variation 740 of the reference clock is shown as a dotted line, and is deemed to be essentially zero. Therefore, any time variation 760 in the acquired and measured reference clock must be the result of, and is deemed to reflect variation in, the timebase of oscilloscope 500. Since both the reference clock and the signal under test are acquired using the same varying timebase, the perceived timing variance 760 of the reference clock may be used to correct the timing variance 720 of the signal under test, to compensate for the errors introduced by timing variation in the oscilloscope.

FIG. 7 illustrates the varying period time trends of the different signals discussed above, shown with a vertical offset from a common time axis 780 for illustration purposes. The ideal or reference clock period trend 740 is deemed to be a straight line (i.e., all clock intervals are identical). The measured reference clock period time trend 760 is deemed to reflect the actual period time trend of the timebase of the test and measurement instrument 500. The uncorrected test period time trend 720 of the signal under test 105 reflects both the period time trend excursions attributable to timebase variations in the oscilloscope and to time variations in the actual signal under test. The resulting difference 700 between the two measurement results 720, 760 in terms of period time trends, represents the actual period time trend of the signal under test. Jitter and timing errors for the signal under test may be determined from period time trend 700.

The frequency of the reference clock 410 may be arbitrary with respect to that of the signal under test, i.e., it does not have to be the same as, or an integer multiple of, the signal under test. Therefore the reference source 614 may be configured to produce a reference clock that has the best timing stability that it is capable of producing. Typically the reference clock is a periodic signal, which is recovered using a software phase-locked loop (PLL) or interval lowpass filtering to eliminate any jitter introduced by the oscilloscope when capturing the reference clock. The resulting period time trend 700 is used to resample or interpolate the samples or edges of the signal under test to determine the times where correction is required. This process may be applied to the signal under test or to some timing information, such as edges, recovered clocks, etc. Various types of interpolation may be used for the resampling, with sinx/x being one example.

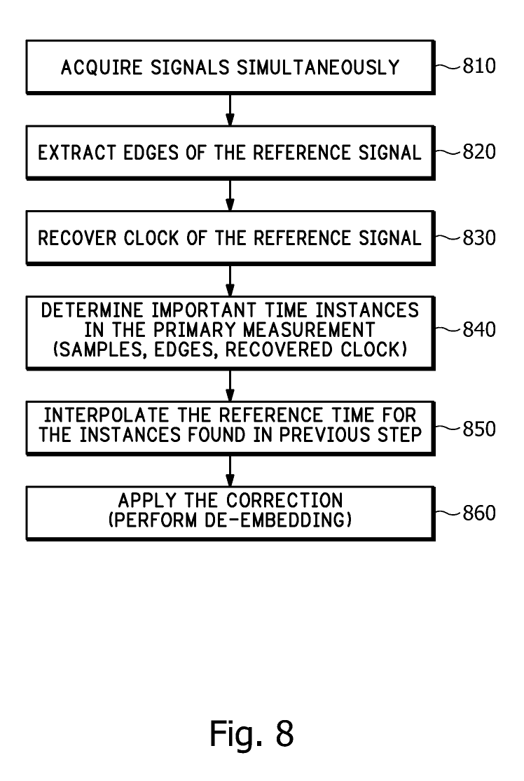

The method is illustrated in FIG. 8. Both the primary signal from the DUT 612 and the “golden” reference signal from the very stable reference source 614 are acquired simultaneously (step 810). The edges from the reference signal are extracted (step 820) and the clock of the reference signal is recovered (step 830). As indicated above, the clock of the reference signal may have a frequency that is arbitrary with respect to that of the primary signal, the desired frequency being a function of the most stable clock produced by the reference source 614. Important time instances in the primary signal, such as samples, edges, recovered clock, etc., are determined (step 840). Using interpolation, the instances in the primary signal are correlated to the reference time (step 850), and the resulting variations are applied to the primary signal to correct for the timebase variations (step 860). The result is a de-embedded primary signal that is free of timebase variations introduced by the measurement instrument.

Thus the present invention provides for timebase variation correction when measuring a signal under test by acquiring simultaneously both the signal under test and a reference signal that is very stable relative to the instrument timebase, and then using the period time trend for the reference signal to compensate the signal under test to produce a period time trend reflecting that truly is present in the signal under test, i.e., substantially free of instrument erroneously timebase variations.

The term “de-embeded” as used herein means “corrected by removing errors that were introduced by the test and measurement instrument”.

What is claimed is:

1. A method of compensating for a varying timebase in a measurement instrument comprising the steps of:
measuring timing variations in a reference clock using the varying timebase of the measurement instrument, the reference clock being very stable in timing with respect to the varying timebase;
simultaneously measuring timing variations in a signal under test using the varying timebase of the measurement instrument; and
compensating for the varying timebase by applying the timing variations of the reference clock to timing variations of the signal under test to determine and correct timing errors in the signal under test.

2. The method as recited in claim 1 further comprising the step of selecting a frequency for the reference clock that provides optimal timing stability.

3. The method as recited in claim 2 wherein the frequency for the reference clock is arbitrary with respect to a clock frequency for the signal under test.

4. The method as recited in claim 1 wherein the compensating step comprises the step of subtracting the reference clock timing variations from the signal under test timing variations to obtain actual timing variations for the signal under test.

5. The method as recited in claim 1 wherein the compensating step comprises the step of resampling timing information from the signal under test timing variations with respect to the reference clock timing variations to obtain actual timing variations for the signal under test.

6. The method as recited in claim 5 wherein the resampling step comprises the steps of:
interpolating the timing information to correlate the timing information with the reference clock to obtain correction values; and
applying the correction values to the signal under test timing variations to obtain the actual timing variations for the signal under test.

7. A test and measurement instrument, comprising:
a first input at which is received a signal under test;
a second input at which is received a reference signal;
a sample clock signal generator for developing a sample clock signal, said sample clock signal exhibiting less stability in timing than said reference signal;
first acquisition circuitry for sampling said signal under test;
second acquisition circuitry for sampling said reference signal;
said signal under test and said reference signal being sampled substantially simultaneously in accordance with said sample clock signal;
a controller for receiving said samples of said signal under test and said reference and measuring timing variations in said samples of said reference signal; and
said controller compensating for variations in said timing of said sample clock signal by applying said timing variations of said reference clock to timing variations of the signal under test to determine and correct timing errors in said signal under test in accordance with a stored timebase variation compensation program.

8. The test and measurement instrument of claim 7 wherein said test and measurement instrument is an oscilloscope.

9. The test and measurement instrument of claim 8, further comprising:
a display device for displaying said variations in said timing of said signal under test.

10. The test and measurement instrument of claim 8, further comprising:
a display device for displaying said variations in said timing of said reference signal.

11. The test and measurement instrument of claim 8, further comprising:
a display device for displaying said variations in said timing of said signal under test that have been corrected with respect to said variations in said timing of said reference signal.

12. The test and measurement instrument of claim 8, further comprising:
a phase locked loop for correcting variations in said reference signal introduced by sampling said reference signal with said sample clock.

13. The test and measurement instrument of claim 8, wherein:
said phase locked loop is a software phase locked loop.
